(19) United States
(12) Patent Application Publication
(10) Pub. No.: US 2026/0368391 A1
(43) Pub. Date: Nov. 19, 2026

(54) CONSTRAINT OPTIMIZATION USING IMPROVED DATA MANAGEMENT

(71) Applicant: Google LLC, Mountain View, CA (US)

(72) Inventors: Bohdan Kivva, Jersey City, NJ (US); Luiz Fernando Lemos do Valle, Princeton, NJ (US); Sergiu lon Goschin, New York, NY (US); Yang Xian, Great Neck, NY (US); Siddhartha Azad, New York, NY (US); Jason Sean Krueger, Seattle, WA (US); Kristina Jinwoo Park, San Francisco, CA (US); Joshua Brian Braverman, Oakland, CA (US)

(21) Appl. No.: 19/210,457

(22) Filed: May 16, 2025

(51) Int. Cl. G06F 30/20; G06Q 30/0242

(52) U.S. Cl. CPC G06F 30/20; G06Q 30/0242

(57) ABSTRACT

Methods, systems, and apparatus, including computer programs encoded on a computer storage medium, for solving constraint optimization problems using simulation data in efficient manners. In one aspect, a method includes identifying a set of parameters for a given digital component campaign. The set of parameters include a target performance parameter that defines a target performance of the given digital component campaign and a set of constraints for the given digital component campaign. Simulation data for digital component campaigns including the given digital component campaign is obtained. For each of multiple candidate scaling factors, the simulation data and results of the given campaign are simulated using the simulation data, the set of constraints, and the candidate scaling factor. A determination is made, based on results of each simulation, a preferred scaling factor that provides a best value for an objective of the given digital component campaign.

### TECHNICAL FIELD

This specification relates to data processing and constraint optimization using efficient data management.

### BACKGROUND

Constraint optimization often involves optimizing (e.g., maximizing) the value of some variable(s) while respecting constraints placed on those or other variables. Constraint optimization is used for many purposes, including resource allocation, scheduling, supply chain management, route planning, and efficiently distributing or recommending content to users.

### SUMMARY

In general, one innovative aspect of the subject matter described in this specification can be embodied in methods that include the actions of identifying a set of parameters for a given digital component campaign, the set of parameters including a target performance parameter that defines a target performance of the given digital component campaign and a set of constraints for the given digital component campaign; obtaining simulation data for multiple digital component campaigns including the given digital component campaign; for each of multiple candidate scaling factors, aggregating the simulation data; and simulating results of the given campaign using the simulation data, the set of constraints, and the candidate scaling factor; determining, based on results of each simulation, a preferred scaling factor that provides a best value for an objective of the given digital component campaign; and distributing digital components of the given digital component campaign using the preferred scaling factor. Other implementations of this aspect include corresponding apparatus, systems, and computer programs, configured to perform the aspects of the methods, encoded on computer storage devices.

These and other embodiments can each optionally include one or more of the following features. In some aspects, the objective for the given digital component campaign includes an increase in volume of user interactions with the digital components of the given digital component campaign, an increase in diversity of user interactions with the digital components of the given digital component campaign, or both.

In some aspects, the objective for the given digital component campaign includes an increase in volume of defined events that occur following user interaction with the digital components of the given digital component campaign, an increase in diversity of defined events that occur following user interaction with the digital components of the given digital component campaign, or both.

In some aspects, each scaling factor is a value to which an expected value parameter for a digital component of the given digital component is scaled to determine a selection value for the digital component.

In some aspects, the selection value for the digital component is further based on a calibration factor for the given digital component campaign.

In some aspects, the selection value for the digital component is further based on the target performance parameter.

In some aspects, the expected value parameter for the digital component varies based on features of a digital component request.

In some aspects, determining, based on results of each simulation, the preferred scaling factor that provides the best value for the objective for the given digital component campaign comprising solving a constraint optimization problem based on the simulation data and the set of constraints.

In some aspects, the set of constraints includes a minimum increase in resources expended by the given digital component campaign, a maximum increase in resources expended by the given digital component campaign, or both.

Particular embodiments of the subject matter described in this specification can be implemented so as to realize one or more of the following advantages. The techniques described in this document enable constraint optimization problems to be solved using simulations when there is a substantial amount of data being used in the simulation.

The techniques described in this document also enable digital component providers to optimize the distribution of digital components to users according to one or more objectives in an efficient manner. For example, the described techniques enable the determination of an optimal (or at least improved) scaling factor that is used to adjust a distribution parameter to distribute digital components to users such that the one or more objectives are achieved or optimized. In a particular example, the scaling factor can be determined for a given digital component campaign using simulations on a large amount of data (e.g., data for thousands or millions of digital component campaigns) to increase the volume of user interactions with digital components of the given digital component campaign, the volume of defined events following user interactions with (or presentations of) the digital components of the given digital component campaign, the diversity of user interactions with digital components of the given digital component campaign, and/or the diversity of defined events for the digital components of the given digital component campaign.

The performance of digital components distributed to users using the scaling factor can then be monitored for various distribution parameters to identify new distribution parameters that provide better performance than previously existing distribution parameters. For example, using an optimal scaling factor to increase volume and/or diversity of interactions or defined events leads to the use of new distribution parameters or existing distribution parameters that were thought to be low performing. If such distribution parameters lead to better performance of the digital components, such distribution parameters can be used to continue distributing digital components to users. Thus, efficient simulations to optimize a scaling factor for a digital component campaign leads to better performance of digital components, which means that more relevant content is being provided to users such that users'online experiences are improved.

Due to the substantial amount of data being used in the simulation, performing the simulation can be computationally intensive. The optimal scaling factor can change based on input variables that change over time (such as market trends or conditions, or factors related to a specific campaign, such as the emergence of competitors), such that the optimal scaling factor can itself evolve over time. Maintaining an accurate estimation of the optimal scaling factor can therefore involve repeating the simulation at different points in time, which further increases computational loads. The described techniques can reduce the computational burden of repeatedly determining an accurate optimal scaling factor. In one example, this is achieved by monitoring one or more input factors or variables on which the optimal scaling factor depends and repeating the simulation when the one or more input factors or variables are determined to meet threshold criteria. In this way, the simulation is only performed as often as necessary. Resource demands can also be monitored on a system performing the simulation and the simulation can be repeated when resource demands are low (such as below a threshold).

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a block diagram of an example environment in which digital components are distributed to client devices.

FIG. 2 is a block diagram of an example optimization system.

FIG. 3 is a flow chart of an example process of determining a scaling factor and using the scaling factor to distribute digital components.

FIG. 4 is a block diagram of an example computer.

Like reference numbers and designations in the various drawings indicate like elements.

### DETAILED DESCRIPTION

This specification describes techniques for optimizing parameters in view of constraints in fast and efficient manners. For example, the specification describes techniques for aggregating data for simulation and constraint optimization based on parameters being optimized and/or constraint parameters. The specification also describes techniques for optimizing parameters of digital component campaigns to improve or optimize for objectives of the digital component campaigns such as user interaction volume, user interaction diversity, defined event volume, and/or defined event diversity.

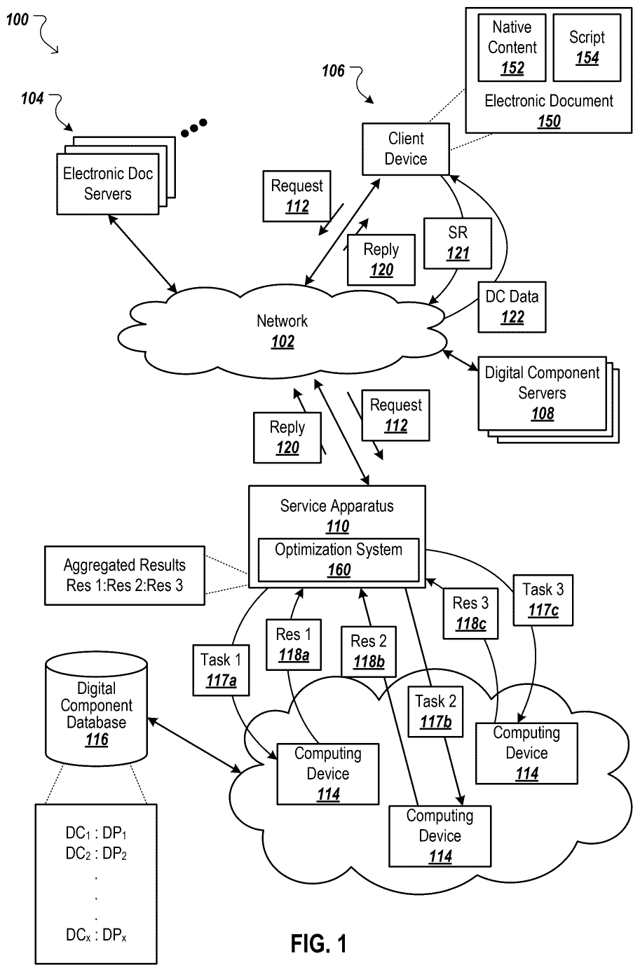

FIG. 1 is a block diagram of an example environment 100 in which digital components are distributed to client devices 106. The example environment 100 includes a network 102, such as a local area network (LAN), a wide area network (WAN), the Internet, or a combination thereof. The network 102 connects electronic document servers 104, client devices 106, digital component servers 108, and a service apparatus 110. The example environment 100 may include many different electronic document servers 104, client devices 106, and digital component servers 108.

The service apparatus 110, which can be implemented as one or more computers in one or more locations, is configured to provide various services to client devices 106, publishers of electronic documents 150, and/or digital component providers that provide digital components to client devices 106, e.g., using the service apparatus 110. In some implementations, the service apparatus 110 can provide search services by providing responses to search queries received from client devices 106. For example, the services apparatus 110 can include a search engine and/or an AI agent or other chat agent that enables users to interact with the agent over the course of conversational queries and responses. The service apparatus 110 can also distribute digital components to client devices 106 for presentation with the responses and/or with electronic documents 150. For example, another search service computer system can send component requests 112 to the service apparatus 110 and these component requests 112 can include one or more queries. In another example, client devices 106 can send component requests 112 to the service apparatus 110, e.g., in response to loading an electronic document 150 that includes a digital component slot for presenting a digital component, as described in more detail below.

As used throughout this document, the phrase “digital component” refers to a discrete unit of digital content or digital information (e.g., a video clip, audio clip, multimedia clip, gaming content, image, text, bullet point, artificial intelligence output, language model output, or another unit of content). A digital component can electronically be stored in a physical memory device as a single file or in a collection of files, and digital components can take the form of video files, audio files, multimedia files, image files, or text files and include advertising information, such that an advertisement is a type of digital component.

A client device 106 is an electronic device capable of requesting and receiving online resources over the network 102. Example client devices 106 include personal computers, gaming devices, mobile communication devices, digital assistant devices, augmented reality devices, virtual reality devices, and other devices that can send and receive data over the network 102. A client device 106 typically includes a user application, such as a web browser, to facilitate the sending and receiving of data over the network 102, but native applications (other than browsers) executed by the client device 106 can also facilitate the sending and receiving of data over the network 102.

A gaming device is a device that enables a user to engage in gaming applications, for example, in which the user has control over one or more characters, avatars, or other rendered content presented in the gaming application. A gaming device typically includes a computer processor, a memory device, and a controller interface (either physical or visually rendered) that enables user control over content rendered by the gaming application. The gaming device can store and execute the gaming application locally or execute a gaming application that is at least partly stored and/or served by a cloud server (e.g., online gaming applications). Similarly, the gaming device can interface with a gaming server that executes the gaming application and “streams” the gaming application to the gaming device. The gaming device may be a tablet device, mobile telecommunications device, a computer, or another device that performs other functions beyond executing the gaming application.

Digital assistant devices include devices that include a microphone and a speaker. Digital assistant devices are generally capable of receiving input by way of voice, and respond with content using audible feedback, and can present other audible information. In some situations, digital assistant devices also include a visual display or are in communication with a visual display (e.g., by way of a wireless or wired connection). Feedback or other information can also be provided visually when a visual display is present. In some situations, digital assistant devices can also control other devices, such as lights, locks, cameras, climate control devices, alarm systems, and other devices that are registered with the digital assistant device.

As illustrated, the client device 106 is presenting an electronic document 150. An electronic document is data that presents a set of content at a client device 106. Examples of electronic documents include webpages, word processing documents, portable document format (PDF) documents, images, videos, search results pages, and feed sources. Native applications (e.g., “apps” and/or gaming applications), such as applications installed on mobile, tablet, or desktop computing devices are also examples of electronic documents. Electronic documents can be provided to client devices 106 by electronic document servers 104 (“Electronic Doc Servers”).

For example, the electronic document servers 104 can include servers that host publisher websites. In this example, the client device 106 can initiate a request for a given publisher webpage, and the electronic document server 104 that hosts the given publisher webpage can respond to the request by sending machine executable instructions that initiate presentation of the given webpage at the client device 106.

In another example, the electronic document servers 104 can include app servers from which client devices 106 can download apps. In this example, the client device 106 can download files required to install an app at the client device 106, and then execute the downloaded app locally (i.e., on the client device). Alternatively, or additionally, the client device 106 can initiate a request to execute the app, which is transmitted to a cloud server. In response to receiving the request, the cloud server can execute the application and stream a user interface of the application to the client device 106 so that the client device 106 does not have to execute the app itself. Rather, the client device 106 can present the user interface generated by the cloud server's execution of the app and communicate any user interactions with the user interface back to the cloud server for processing.

Electronic documents can include a variety of content. For example, an electronic document 150 can include native content 152 that is within the electronic document 150 itself and/or does not change over time. Electronic documents can also include dynamic content that may change over time or on a per-request basis. For example, a publisher of a given electronic document (e.g., electronic document 150) can maintain a data source that is used to populate portions of the electronic document. In this example, the given electronic document can include a script, such as the script 154, that causes the client device 106 to request content (e.g., a digital component) from the data source when the given electronic document is processed (e.g., rendered or executed) by a client device 106 (or a cloud server). The client device 106 (or cloud server) integrates the content (e.g., digital component) obtained from the data source into the given electronic document to create a composite electronic document including the content obtained from the data source.

In some situations, a given electronic document (e.g., electronic document 150) can include a digital component script (e.g., script 154) that references the service apparatus 110, or a particular service provided by the service apparatus 110. In these situations, the digital component script is executed by the client device 106 when the given electronic document is processed by the client device 106. Execution of the digital component script configures the client device 106 to generate a request for digital components (referred to as a “component request”), which is transmitted over the network 102 to the service apparatus 110. For example, the digital component script can enable the client device 106 to generate a packetized data request including a header and payload data. The component request 112 can include event data specifying features such as a name (or network location) of a server from which the digital component is being requested, a name (or network location) of the requesting device (e.g., the client device 106), and/or information that the service apparatus 110 can use to select one or more digital components, or other content, provided in response to the request. The component request 112 is transmitted, by the client device 106, over the network 102 (e.g., a telecommunications network) to a server of the service apparatus 110.

The component request 112 can include event data specifying other event features, such as the electronic document being requested and characteristics of locations of the electronic document at which the digital component can be presented. For example, event data specifying a reference (e.g., URL) to an electronic document (e.g., webpage) in which the digital component will be presented, available locations of the electronic documents that are available to present digital components, sizes of the available locations, and/or media types that are eligible for presentation in the locations can be provided to the service apparatus 110. Similarly, event data specifying keywords associated with the electronic document (“document keywords”) or entities (e.g., people, places, or things) that are referenced by the electronic document can also be included in the component request 112 (e.g., as payload data) and provided to the service apparatus 110 to facilitate identification of digital components that are eligible for presentation with the electronic document.

The event data can also include a search query that was submitted from the client device 106 to obtain a search results page or a response in a conversational user interface. For example, an AI agent or other form of a chat agent can provide a conversational user interface in which users can provide natural language queries, which can be in the form of prompts for a language model and receive responses to the queries. The user can refine their expression of their informational needs as the conversation progresses and the AI agent can send component requests 112 with the updated queries.

Component requests 112 can also include event data related to other information, such as information that a user of the client device has provided, geographic information indicating a state or region from which the component request was submitted, or other information that provides context for the environment in which the digital component will be displayed (e.g., a time of day of the component request, a day of the week of the component request, a type of device at which the digital component will be displayed, such as a mobile device or tablet device). Component requests 112 can be transmitted, for example, over a packetized network, and the component requests 112 themselves can be formatted as packetized data having a header and payload data. The header can specify a destination of the packet and the payload data can include any of the information discussed above.

The service apparatus 110 chooses digital components (e.g., third-party content, such as video files, audio files, images, text, gaming content, augmented reality content, and combinations thereof, which can all take the form of advertising content or non-advertising content) that will be presented with the given electronic document (e.g., at a location specified by the script 154) in response to receiving the component request 112 and/or using information included in the component request 112.

Delays in providing digital components in response to a component request 112 can result in page load errors at the client device 106 or cause portions of the electronic document to remain unpopulated even after other portions of the electronic document are presented at the client device 106. Also, as the delay in providing the digital component to the client device 106 increases, it is more likely that the electronic document will no longer be presented at the client device 106 when the digital component is delivered to the client device 106, thereby negatively impacting a user's experience with the electronic document. Further, delays in providing the digital component can result in a failed delivery of the digital component, for example, if the electronic document is no longer presented at the client device 106 when the digital component is provided. The described techniques are adapted to select and provide digital components in a short amount of time such that these errors and user experience impact are reduced or eliminated.

In some implementations, the service apparatus 110 is implemented in a distributed computing system that includes, for example, a server and a set of multiple computing devices 114 that are interconnected and identify and distribute digital components in response to requests 112. The set of multiple computing devices 114 operate together to identify a set of digital components that are eligible to be presented in the electronic document from among a corpus of millions of available digital components (DC₁₋ₓ). The set of digital components can include customizable digital components. The millions of available digital components can be indexed, for example, in a digital component database 116. Each digital component index entry can reference the corresponding digital component and/or include distribution parameters (DP₁-DPₓ) that contribute to (e.g., trigger, condition, or limit) the distribution/transmission of the corresponding digital component. For example, the distribution parameters can contribute to (e.g., trigger) the transmission of a digital component by requiring that a component request include at least one criterion that matches (e.g., either exactly or with some pre-specified level of similarity) one of the distribution parameters of the digital component.

In some implementations, the distribution parameters for a particular digital component can include distribution keywords that must be matched (e.g., by electronic documents, document keywords, and/or terms specified in the component request 112) in order for the digital component to be eligible for presentation. Additionally, or alternatively, the distribution parameters can include embeddings that can use various different dimensions of data, such as website details and/or consumption details (e.g., page viewport, user scrolling speed, or other information about the consumption of data). The distribution parameters can require that the component request 112 include information specifying a particular geographic region (e.g., country or state) and/or information specifying that the component request 112 originated at a particular type of client device (e.g., mobile device or tablet device) in order for the digital component to be eligible for presentation. The distribution parameters can specify dates, days of the week, and/or times at which the digital component is eligible for presentation.

The distribution parameters can specify an eligibility value or selection value (e.g., ranking score, or some other specified value) that is used for evaluating the eligibility of the digital component for distribution/transmission (e.g., among other available digital components). The selection value can indicate an amount (e.g., a monetary amount) that a digital component provider is willing to provide to a publisher for the digital component to be presented with a resource of the publisher. The distribution parameters can specify different selection values based on other distribution parameters, e.g., based on keywords, geographic location, time of day, day of week, date, etc.

The identification of the eligible digital component can be segmented into multiple tasks 117a-117c that are then assigned among computing devices within the set of multiple computing devices 114. For example, different computing devices in the set 114 can each analyze a different portion of the digital component database 116 to identify various digital components having distribution parameters that match information included in the component request 112. In some implementations, each given computing device in the set 114 can analyze a different data dimension (or set of dimensions) and pass (e.g., transmit) results (Res 1-Res 3) 118a-118c of the analysis back to the service apparatus 110. For example, the results 118a-118c provided by each of the computing devices in the set 114 may identify a subset of digital components that are eligible for distribution in response to the component request and/or a subset of the digital component that have certain distribution parameters. The identification of the subset of digital components can include, for example, comparing the event data to the distribution parameters, and identifying the subset of digital components having distribution parameters that match at least some features of the event data.

The service apparatus 110 aggregates the results 118a-118c received from the set of multiple computing devices 114 and uses information associated with the aggregated results to select one or more digital components that will be provided in response to the request 112. For example, the service apparatus 110 can select a set of winning digital components (one or more digital components) based on the outcome of one or more content evaluation processes, as discussed below. In turn, the service apparatus 110 can generate and transmit, over the network 102, reply data 120 (e.g., digital data representing a reply) that enable the client device 106 to integrate the set of winning digital components into the given electronic document, such that the set of winning digital components (e.g., winning third-party content) and the content of the electronic document are presented together at a display of the client device 106. If a customizable digital component is a winning digital component, the service apparatus 110 can generate a new digital component using the selected assets and layout for the customizable digital component prior to sending the new digital component to the client device 106. In some implementations, the client device 106 executes instructions included in the reply data 120, which configures and enables the client device 106 to obtain the set of winning digital components from one or more digital component servers 108. For example, the instructions in the reply data 120 can include a network location (e.g., a Uniform Resource Locator (URL)) and a script that causes the client device 106 to transmit a server request (SR) 121 to the digital component server 108 to obtain a given winning digital component from the digital component server 108. In response to the request, the digital component server 108 will identify the given winning digital component specified in the server request 121 (e.g., within a database storing multiple digital components) and transmit to the client device 106, digital component data (DC Data) 122 that presents the given winning digital component in the electronic document at the client device 106.

When the client device 106 receives the digital component data 122, the client device will render the digital component (e.g., third-party content), and present the digital component at a location specified by, or assigned to, the script 154. For example, the script 154 can create a walled garden environment, such as a frame, that is presented within, e.g., beside, the native content 152 of the electronic document 150. In some implementations, the digital component is overlayed over (or adjacent to) a portion of the native content 152 of the electronic document 150, and the service apparatus 110 can specify the presentation location within the electronic document 150 in the reply 120. For example, when the native content 152 includes video content, the service apparatus 110 can specify a location or object within the scene depicted in the video content over which the digital component is to be presented.

The service apparatus 110 can also include an optimization system 160. Although shown as a part of the service apparatus, the optimization system 160 can be a separate system that is communicatively coupled to the service apparatus 110, e.g., via the network 102.

The optimization system is configured to determine distribution parameters for a digital component campaign that includes one or more digital components of a digital component provider. For example, the optimization system 160 can be configured to determine a scaling factor that is used to adjust selection value parameters that are used to determine the selection value for the digital component(s) of the digital component campaign.

As described above, a selection value can vary for different distribution parameters. The selection value for a set of distribution parameters can be based on multiple selection value parameters. One selection value parameter can be an expected value parameter for the digital component, which can vary based on the context in which the digital component will be presented. Thus, a respective expected value can be assigned to, or dynamically determined for, each set of distribution parameters. For example, a first set of one or more keywords may have a first expected value while a second set of one or more keywords may have a second expected value that is different from the first expected value. In another example, a first set of keywords at a first time may have a first expected value while that same first set of keywords may have a second expected value at a second time that is different from the first time.

The selection value for a digital component campaign can be based on a target performance parameter that defines a target performance of the digital component campaign. In some implementations, the target performance parameter defines a target performance based on an amount of resources expended for the digital component campaign. For example, the target performance can specify a target return on (e.g., a target amount of resources received for) the resource expenditure.

The selection value for a digital component campaign can be based on a calibration factor. The calibration factor can be adjusted over time to ensure that an appropriate number of digital components are provided for presentation throughout a given time period, e.g., without depleting the resources for the digital component campaign before the end (or more than a threshold amount of time) before the end of the given time period.

When selecting a digital component to provide in response to a component request 112, the service apparatus 110 can determine the selection value for a digital component of the digital component campaign based on the selection value parameters. The selection value can be based on any combination of the selection value parameters. For example, the selection value can be based on any combination of the calibration factor, the target performance parameter, and/or the expected value. As described above, the expected value can be based on the distribution parameters, e.g., based on which distribution parameters match the event data of the component request 112.

In some implementations, the service apparatus 110 can scale the expected value parameter using a scaling factor that is determined by the optimization system 160. The optimization system 160 can determine the scaling factor for a digital component campaign to optimize (e.g., maximize) an objective or multiple objectives, or at least identify a preferred, improved, or increased value of the objective or multiple objectives. The objective(s) can be related to the performance of the digital component campaign and/or to the reach of the digital component campaign.

One example objective is to increase the number of sets of distribution parameters for which digital campaigns are provided. For example, the objective can be to increase or maximize the number of keywords (or set of keywords) for which a digital component of the digital component campaign is provided when the keywords are included in component requests 112. This objective can also be referred to as presentation diversity.

Another example objective is to increase the number of times that the digital components of the digital component campaign receive a user interaction (e.g., click on or selection of the digital component) when the digital components are presented to users in response to component requests that include event data matching the distribution parameters. For example, this objective can be to maximize the total number of user interactions with the digital components of the digital component campaign, e.g., independent of the distribution parameters for which the digital components are presented. This objective can also be referred to as a user interaction volume objective.

Another example objective is to increase the number of times a defined event occurs following the digital components being presented to users (or interacted with by users) in response to component requests that include event data matching the distribution parameters. For example, this objective can be to maximize the total number of occurrences of the defined events that result from users viewing or interacting with the digital components of the digital component campaign. This objective can also be referred to as a defined event volume objective.

The defined event can be any type of event following presentation of a digital component or user interaction with the digital component. For example, the defined event can be the user subscribing to a newsletter after selecting a digital component and visiting a landing page related to the newsletter. Another example defined event can be the user adding an item that is the subject of a digital component to a virtual shopping cart or purchasing the item after selecting the digital component can visiting a landing page related to the item.

Another example objective is to increase the number of sets of distribution parameters for which the digital components of the digital component campaign receive a user interaction (e.g., click on or selection of the digital component) when the digital components are presented to users in response to component requests that include event data matching the distribution parameters. For example, this objective can be to maximize the number of different keywords that result in users interacting with the digital components of the digital component campaign. This objective can also be referred to as a user interaction diversity objective.

Another example objective is to increase the number of sets of distribution parameters for which a defined event occurs following the digital components being presented to users (or interacted with by users) in response to component requests that include event data matching the distribution parameters. For example, this objective can be to maximize the number of different defined events that result from users viewing or interacting with the digital components of the digital component campaign. This objective can also be referred to as a defined event diversity objective.

Another example objective is to increase the value of the defined events that occur following user interactions with the digital components of the digital component campaign. For example, the occurrence of defined events can have values (e.g., monetary values for purchases) that vary across occurrences of the events. This objective can also be referred to as a value objective.

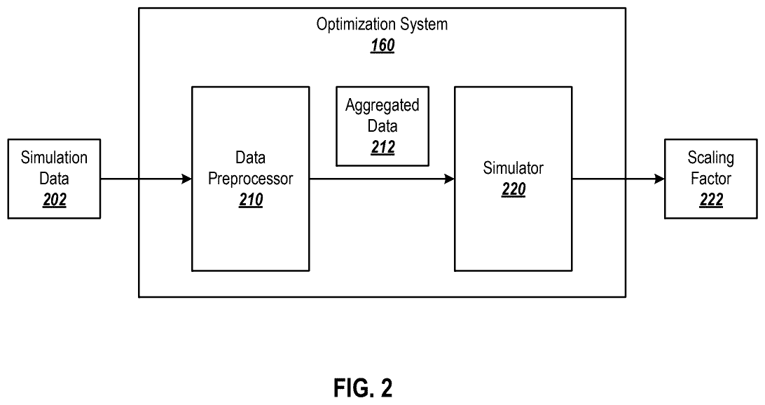

The optimization system 160 is configured to determine a scaling factor that, when applied to expected values of a digital component campaign, optimizes or at least satisfies one or more of these objectives. An objective can be satisfied even if it is not the optimal solution if the result is an increase in a value associated with the objective (e.g., an increase in volume or diversity). For example, the objective can be satisfied if the increase is an increase that meets or exceeds a threshold amount or percentage. An example optimization system 160 is described in more detail with reference to FIG. 2.

After being determined, the scaling factor for a digital component campaign can be used to scale the selection value that is used to select digital components in response to component requests 112. When the service apparatus 110 receives a component request 112, the service apparatus 110 can determine selection values for digital components that are eligible to be provided in response to the component request 112 based on distribution parameters for the digital component matching event data of the component request 112. For those matching distribution parameters, the service apparatus 112 can obtain an expected value for a digital component and scale that expected value using the scaling factor of the digital component campaign to which the digital component belongs. In some implementations, the service apparatus 110 scales the expected value by raising the expected value by an exponent equal to or proportional to the scaling factor. The service apparatus 110 can then determine the selection value for the digital component based on the scaled expected value and any other selection value parameters being used to determine the selection value.

The service apparatus 110 can then select from the eligible digital components using the selection values for the eligible digital components and optionally other criteria. For example, the service apparatus 110 can select the digital component having the highest selection value and provide digital component data for the selected digital component to the client device 106 from which the component request 112 was received.

FIG. 2 is a block diagram of an example optimization system 160. In general, the optimization system 160 can perform techniques to determine a scaling factor for a digital component campaign that optimizes one or more objectives, e.g., one or more of the objectives described above with reference to FIG. 1. The example optimization system 160 includes a data preprocessor 210 and a simulator 220, each of which can be implemented using one or more computers in one or more locations.

The optimization system 160 can determine the scaling factor 222 for a digital component campaign subject to a set of one or more constraints and/or using a lower target performance parameter for the digit. For example, the service apparatus 110 can be configured to make digital components of the digital component campaign eligible for certain sets of distribution parameters (e.g., specific keywords, times of day, etc.) that have previously resulted in good performance for the digital components. Similarly, the service apparatus 110 can be configured to make the digital components ineligible for sets of distribution parameters that are known to not provide good performance, have an unknown performance, and/or do not occur enough to have meaningful data. By reducing the target performance parameter for the digital component campaign, the optimization system 160 can explore whether these other sets of distribution parameters will, or are likely to, improve upon the objective(s), e.g., by resulting in user interactions or defined events.

The set of constraints can include, for example, an amount of resources available for use by the digital component campaign (e.g., over a given time period), a maximum increase in the amount of resources of the digital component campaign used over the given time period (e.g., relative to a baseline amount of resources to be used), and/or a minimum increase in the amount of resources of the digital component campaign used over the given time period, e.g., relative to the baseline amount of resources to be used. The resources can be a monetary amount that is depleted when the digital components are distributed to client devices 106 in response to component requests. For example, each digital component campaign can have a budget of a given amount of resources for each time period.

In some implementations, the optimization system 160 performs constraint optimization techniques to determine a scaling factor 222 that optimizes one or more of the objectives described above while respecting the set of constraints. In some implementations, the optimization system 160 uses simulation data 202 when performing the constraint optimization techniques. The simulation data can include, for example, features of component requests (e.g., event data of component requests) and campaign data for multiple (e.g., thousands or millions of) digital component campaigns including the digital component campaign for which the scaling factor 222 is being determined. The campaign data for a digital component campaign can include, for example, distribution parameters, an amount of resources, a target performance, and/or other appropriate data for a digital component campaign.

In some implementations, the simulation data 202 includes actual historical data from historical digital component campaigns and event data of actual component requests 112. In some implementations, the simulation data 202 is generated based on historical data, based on expert knowledge of digital component campaigns, and/or using machine learning models.

In some implementations, the optimization techniques include simulating, by the simulator 220, the digital component campaigns based on each of multiple candidate scaling factors for a given campaign for which the scaling factor 222 that optimizes the objective(s) is being determined. For each candidate scaling factor, the simulator 220 can simulate all of the digital component campaigns based on the simulated component requests to determine, for which sets of distribution parameters (e.g., which keyword(s)), digital components of the given digital component campaign are selected for presentation at client devices 106, the number of presentations of the digital components for each set of distribution parameters, which sets of distribution parameters result in user interactions when presented, the number of user interactions with the digital components for each set of distribution parameters, which sets of distribution parameters result in occurrences of a defined event following presentation of and/or user interaction with the digital components, and/or the number of occurrences of the defined events following presentation of and/or user interaction with the digital components for each set of distribution parameters.

Given this data for each candidate scaling factor, the optimization system 160 can determine which of the candidate scaling factors provides the best or most optimal result for each objective that is being optimized. For example, if the user interaction volume is being optimized, the optimization system 160 can select the scaling factor 222 that results in the highest number of user interactions for digital components of the given digital component campaign.

As the amount of simulation data for thousands or millions of digital component campaigns and thousands or millions of component requests 112 would be substantial, the optimization system 160 includes the data preprocessor 210, which can preprocess the simulation data to improve the efficiency of the constraint optimization techniques. In some implementations, the optimization system 160 aggregates the simulation differently based on the candidate scaling factor and/or other parameters of the given digital component campaign.

In some implementations, the simulation and optimization of the scaling factor are performed as follows. The optimization system 160 receives a strategy (e.g., digital component campaign) and simulates how it thinks the strategy would perform in different digital component selection scenarios based on historical presentations of digital components and using values for the scaling factor and a simulation multiplier (k). The other inputs for a simulation can include, for example, initial values of the scaling factor and the simulation multiplier. The outputs of the simulation can include performance metrics, e.g., number of user interactions with digital components of the digital component campaign, number of defined events for digital components of the digital component campaign, the value of the defined events, and the amount of resources expended by the digital component campaign.

Based on the above, this means that the optimization system 160 takes into account strategy data and digital component selection data. Strategy data can include, for example, historical campaign performance, campaign's defined event profile, target set, age of campaign, type of distribution strategy being used in the campaign, the amount of resources for the campaign, digital component creatives, and/or other data relevant to a digital component campaign. The digital component selection data can include, for example, queries and contextual data for the queries (e.g., location of query, time of day, etc.), consumer profile, historical search data, and/or other data relevant to processes for selecting digital components from a set of candidate digital components.

For a given query (e.g., set of event data) for which a digital component of the digital component campaign can be displayed, the optimization system determines a selection value for the digital component campaign. The selection value calculation can vary based on the performance metric being optimized (e.g., user interactions or defined events), but can in general be based on the target performance for the digital component campaign, the expected value for the query, the scaling factor, and the simulation multiplier.

The simulation techniques include determining values of the scaling factor and the simulation multiplier in the calculations of the selection values for a given strategy. These values are unique per strategy and updated periodically (e.g., daily, weekly, monthly, etc.). The optimization system 160 uses simulation data and calculates the values of the scaling factor and the simulation multiplier to determine a selection value for a given expected value for a given query that will maximize the incremental value seen for the next incremental amount of resources expended from the digital component campaign.

To set up the data for the simulation, the optimization system 160 can calculate the scaling factor and simulation multiplier values for the strategy. The simulation data and these values can be updated periodically. The optimization system 160 can aggregate the simulation data in the form of:

### Input:

L=[(k, α)→resources expended, selective value metrics, defined events, . . . |(k, α)∈grid]

Here, the parameter α represents the scaling factor. The optimization system 160 can use this aggregated data to more efficiently run the simulation and identify the scaling factor that provides the best result for the objective of the digital component campaign.

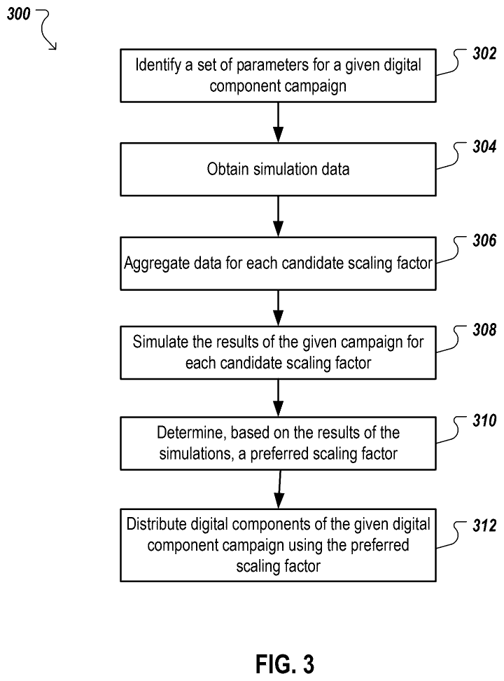

FIG. 3 is a flow chart of an example process 300 of determining a scaling factor and using the scaling factor to distribute digital components. Operations of the process 300 can be performed, for example, by the service apparatus 110 of FIG. 1 (e.g., by the optimization system 160), or another data processing apparatus. The operations of the process 300 can also be implemented as instructions stored on a computer readable medium, which can be non-transitory. Execution of the instructions, by one or more data processing apparatus, causes the one or more data processing apparatus to perform operations of the process 300. For brevity, the process 300 is described in terms of being performed by a system.

The system identifies a set of constraints for a given digital component campaign (302). The set of parameters can include a target performance parameter that defines a target performance of the given digital component campaign and a set of constraints for the given digital component campaign. The set of parameters can also include, for example, distribution parameters, expected values for distribution parameters, a calibration factor, an amount of resources, and/or other appropriate data for a digital component campaign.

The system obtains simulation data (304). As described above, the simulation data can include campaign data for multiple digital component campaigns and event data for multiple component requests.

The system aggregates the simulation data for each of multiple candidate scaling factors (306). For example, the system can identify a set of candidate scaling factors for a constraint optimization problem and aggregate the simulation data differently for each candidate scaling factor.

The system simulates the results of the given digital component campaign for each candidate scaling factor (308). The system can use the aggregated simulation data for each candidate scaling factor to simulate the results for each of multiple component requests. The results for each component request can include, which digital component(s) were provided in response to the component request, which if any provided digital component received a user interaction in response to being presented, and which if any provided digital component led to a defined event. Using this data, the system can determine, for the given digital component campaign, determine, for which sets of distribution parameters (e.g., which keyword(s)), digital components of the given digital component campaign are selected for presentation at client devices 106, the number of presentations of the digital components for each set of distribution parameters, which sets of distribution parameters result in user interactions when presented, the number of user interactions with the digital components for each set of distribution parameters, which sets of distribution parameters result in occurrences of a defined event following presentation of and/or user interaction with the digital components, and/or the number of occurrences of the defined events following presentation of and/or user interaction with the digital components for each set of distribution parameters.

The system determines, based on the results of the simulations, a preferred scaling factor for the given digital component campaign (310). For example, the system can determine, as the preferred scaling factor, the candidate scaling factor, that provides the best or most optimal result for each objective that is being optimized. For example, if the user interaction diversity is being optimized, the optimization system 160 can select the scaling factor 222 that results in the highest number of sets of distribution parameters for which user interactions are recorded in the simulations for digital components of the given digital component campaign.

Digital components of the given digital component campaign are distributed to client devices using the preferred scaling factor (312). The system can provide the preferred scaling factor to a runtime system that determines selection values for the digital components of the given digital component campaign. This system can determine the selection value for the digital components of the given digital component campaign for component requests by scaling an expected value by the scaling factor, as described above. This system is configured to select digital components to distribute to client devices in response to component requests based on the selection values for the digital components that are eligible for selection.

The method 300 can include a further operation, e.g., after operation 312 (or before operation 302), of monitoring one or more input factors or variables on which the optimal scaling factor depends and repeating the method 300 (or determining to initiate the method 300) when the one or more input factors or variables are determined to have changed by (or otherwise meet) threshold criteria. In other words, the operations of 302-312 can be repeated when it is determined that variables relevant to the optimal scaling factors have changed to a significant degree, such that recalculation of the optimal scaling factor is appropriate or necessary to maintain accuracy. The monitored input factors or variables can be any suitable factors or variables that change over time, such as market conditions (e.g., local inflation values, consumer spending in the specific field relevant to the campaign of interest), or campaign-specific factors, such as a budget associated with the campaign, sales performance of the underlying product or service, or any other suitable factor or variable. The threshold criteria can be of any suitable kind, such as a percentage change, and adapted to the monitored input factors or input variables. This allows the optimal scaling factor to be recalculated only when appropriate, to avoid performing repeated computationally intensive simulations. Alternatively, or in addition, determining when to repeat the method 300 can also be based on the availability of computing resources. For example, the method 300 can be scheduled to be performed on a system (e.g., the system 400 described below) at a time when computational demands on the system tend to be lower. A combination of both approaches can also be taken. For example, the method 300 may be repeated only after the monitored input variables or factors have been determined to have changed by the threshold amount, and then repeated at the next time period where a demand for computing resources is low or below a threshold.

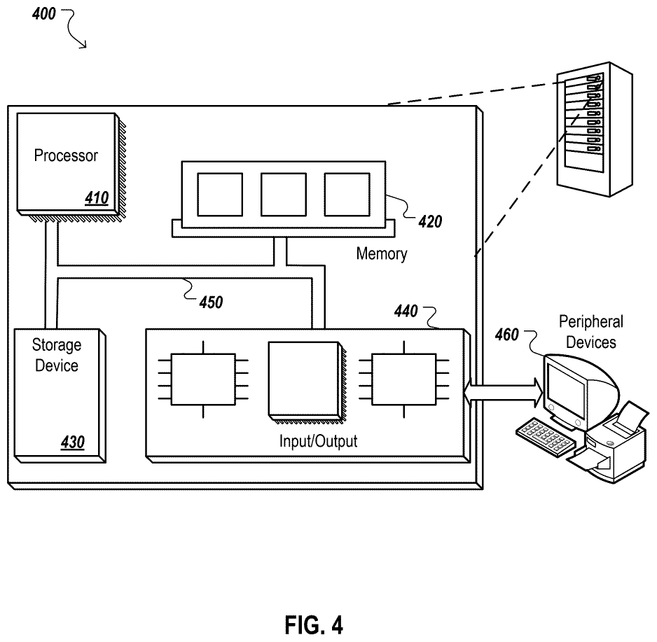

FIG. 4 is a block diagram of an example computer system 400 that can be used to perform operations described above. The system 400 includes a processor 410, a memory 420, a storage device 430, and an input/output device 440. Each of the components 410, 420, 430, and 440 can be interconnected, for example, using a system bus 450. The processor 410 is capable of processing instructions for execution within the system 400. In one implementation, the processor 410 is a single-threaded processor. In another implementation, the processor 410 is a multi-threaded processor. The processor 410 is capable of processing instructions stored in the memory 420 or on the storage device 430.

The memory 420 stores information within the system 400. In one implementation, the memory 420 is a computer-readable medium. In one implementation, the memory 420 is a volatile memory unit. In another implementation, the memory 420 is a non-volatile memory unit.

The storage device 430 is capable of providing mass storage for the system 400. In one implementation, the storage device 430 is a computer-readable medium. In various different implementations, the storage device 430 can include, for example, a hard disk device, an optical disk device, a storage device that is shared over a network by multiple computing devices (e.g., a cloud storage device), or some other large capacity storage device.

The input/output device 440 provides input/output operations for the system 400. In one implementation, the input/output device 440 can include one or more of a network interface devices, e.g., an Ethernet card, a serial communication device, e.g., and RS-232 port, and/or a wireless interface device, e.g., and 802.11 card. In another implementation, the input/output device can include driver devices configured to receive input data and send output data to other devices, e.g., keyboard, printer, display, and other peripheral devices 460. Other implementations, however, can also be used, such as mobile computing devices, mobile communication devices, set-top box television client devices, etc.

Although an example processing system has been described in FIG. 4, implementations of the subject matter and the functional operations described in this specification can be implemented in other types of digital electronic circuitry, or in computer software, firmware, or hardware, including the structures disclosed in this specification and their structural equivalents, or in combinations of one or more of them.

An electronic document (which for brevity will simply be referred to as a document) does not necessarily correspond to a file. A document may be stored in a portion of a file that holds other documents, in a single file dedicated to the document in question, or in multiple coordinated files.

For situations in which the systems discussed here collect and/or use personal information about users, the users may be provided with an opportunity to enable/disable or control programs or features that may collect and/or use personal information (e.g., information about a user's social network, social actions or activities, a user's preferences, or a user's current location). In addition, certain data may be treated in one or more ways before it is stored or used, so that personally identifiable information associated with the user is removed. For example, a user's identity may be anonymized so that the no personally identifiable information can be determined for the user, or a user's geographic location may be generalized where location information is obtained (such as to a city, ZIP code, or state level), so that a particular location of a user cannot be determined.

Embodiments of the subject matter and the operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer programs, i.e., one or more modules of computer program instructions, encoded on computer storage medium for execution by, or to control the operation of, data processing apparatus. Alternatively, or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described in this specification can be implemented as operations performed by a data processing apparatus on data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

This document refers to a service apparatus. As used herein, a service apparatus is one or more data processing apparatus that perform operations to facilitate the distribution of content over a network. The service apparatus is depicted as a single block in block diagrams. However, while the service apparatus could be a single device or single set of devices, this disclosure contemplates that the service apparatus could also be a group of devices, or even multiple different systems that communicate in order to provide various content to client devices. For example, the service apparatus could encompass one or more of a search system, a video streaming service, an audio streaming service, an email service, a navigation service, an advertising service, a gaming service, or any other service.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing actions in accordance with instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits data (e.g., an HTML page) to a client device (e.g., for purposes of displaying data to and receiving user input from a user interacting with the client device). Data generated at the client device (e.g., a result of the user interaction) can be received from the client device at the server.

While this specification contains many specific implementation details, these should not be construed as limitations on the scope of any inventions or of what may be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

What is claimed is:

1. A method comprising:
identifying a set of parameters for a given digital component campaign, the set of parameters comprising a target performance parameter that defines a target performance of the given digital component campaign and a set of constraints for the given digital component campaign;
obtaining simulation data for a plurality of digital component campaigns comprising the given digital component campaign;
for each of multiple candidate scaling factors,
aggregating the simulation data; and
simulating results of the given campaign using the simulation data, the set of constraints, and the candidate scaling factor;
determining, based on results of each simulation, a preferred scaling factor that provides a best value for an objective of the given digital component campaign; and
distributing digital components of the given digital component campaign using the preferred scaling factor.

2. The method of claim 1, wherein the objective for the given digital component campaign comprises an increase in volume of user interactions with the digital components of the given digital component campaign, an increase in diversity of user interactions with the digital components of the given digital component campaign, or both.

3. The method of claim 1, wherein the objective for the given digital component campaign comprises an increase in volume of defined events that occur following user interaction with the digital components of the given digital component campaign, an increase in diversity of defined events that occur following user interaction with the digital components of the given digital component campaign, or both.

4. The method of claim 1, wherein each scaling factor is a value to which an expected value parameter for a digital component of the given digital component is scaled to determine a selection value for the digital component.

5. The method of claim 4, wherein the selection value for the digital component is further based on a calibration factor for the given digital component campaign.

6. The method of claim 4, wherein the selection value for the digital component is further based on the target performance parameter.

7. The method of claim 4, wherein the expected value parameter for the digital component varies based on features of a digital component request.

8. The method of claim 1, wherein determining, based on results of each simulation, the preferred scaling factor that provides the best value for the objective for the given digital component campaign comprising solving a constraint optimization problem based on the simulation data and the set of constraints.

9. The method of claim 1, wherein the set of constraints comprise a minimum increase in resources expended by the given digital component campaign, a maximum increase in resources expended by the given digital component campaign, or both.

10. A system comprising:
one or more processors; and
one or more storage devices storing instructions that, when executed by the one or more processors, cause the one or more processors to perform operations comprising:
identifying a set of parameters for a given digital component campaign, the set of parameters comprising a target performance parameter that defines a target performance of the given digital component campaign and a set of constraints for the given digital component campaign;
obtaining simulation data for a plurality of digital component campaigns comprising the given digital component campaign;
for each of multiple candidate scaling factors,
aggregating the simulation data; and
simulating results of the given campaign using the simulation data, the set of constraints, and the candidate scaling factor;
determining, based on results of each simulation, a preferred scaling factor that provides a best value for an objective of the given digital component campaign; and
distributing digital components of the given digital component campaign using the preferred scaling factor.

11. The system of claim 10, wherein the objective for the given digital component campaign comprises an increase in volume of user interactions with the digital components of the given digital component campaign, an increase in diversity of user interactions with the digital components of the given digital component campaign, or both.

12. The system of claim 10, wherein the objective for the given digital component campaign comprises an increase in volume of defined events that occur following user interaction with the digital components of the given digital component campaign, an increase in diversity of defined events that occur following user interaction with the digital components of the given digital component campaign, or both.

13. The system of claim 10, wherein each scaling factor is a value to which an expected value parameter for a digital component of the given digital component is scaled to determine a selection value for the digital component.

14. The system of claim 13, wherein the selection value for the digital component is further based on a calibration factor for the given digital component campaign.

15. The system of claim 13, wherein the selection value for the digital component is further based on the target performance parameter.

16. The system of claim 13, wherein the expected value parameter for the digital component varies based on features of a digital component request.

17. The system of claim 10, wherein determining, based on results of each simulation, the preferred scaling factor that provides the best value for the objective for the given digital component campaign comprising solving a constraint optimization problem based on the simulation data and the set of constraints.

18. The system of claim 10, wherein the set of constraints comprise a minimum increase in resources expended by the given digital component campaign, a maximum increase in resources expended by the given digital component campaign, or both.

19. A non-transitory computer readable storage medium carrying instructions that, when executed by one or more processors, cause the one or more processors to perform operations comprising:
identifying a set of parameters for a given digital component campaign, the set of parameters comprising a target performance parameter that defines a target performance of the given digital component campaign and a set of constraints for the given digital component campaign;
obtaining simulation data for a plurality of digital component campaigns comprising the given digital component campaign;
for each of multiple candidate scaling factors,
aggregating the simulation data; and
simulating results of the given campaign using the simulation data, the set of constraints, and the candidate scaling factor;
determining, based on results of each simulation, a preferred scaling factor that provides a best value for an objective of the given digital component campaign; and
distributing digital components of the given digital component campaign using the preferred scaling factor.

20. The non-transitory computer readable storage medium of claim 19, wherein the objective for the given digital component campaign comprises an increase in volume of user interactions with the digital components of the given digital component campaign, an increase in diversity of user interactions with the digital components of the given digital component campaign, or both.
